(19) United States
(12) Patent Application Publication
(10) Pub. No.: US 2025/0335927 A1
(43) Pub. Date: Oct. 30, 2025

(54) PRESSURE DATA FOR UTILITY MONITORING

(71) Applicant: Ademco Inc., Golden Valley, MN (US)

(72) Inventors: Kenneth Eskildsen, Great Neck, NY (US); David Quam, Maple Grove, MN (US); John Edward Cronin, Jericho, VT (US); Adam CH Myre, Minnetonka, MN (US)

(73) Assignee: Ademco Inc., Golden Valley, MN (US)

(21) Appl. No.: 18/870,719

(22) PCT Filed: May 19, 2023
(86) PCT No.: PCT/US2023/022893

§ 371 Date: Dec. 2, 2024

Related U.S. Application Data
(60) Provisional application No. 63/348,195, filed on Jun. 2, 2022.

(51) Int. Cl. G06Q 30/012; G01L 13/00; G06Q 10/20; G08B 21/18

(52) U.S. Cl. CPC G06Q 30/012; G01L 13/00; G06Q 10/20; G08B 21/182

(57) ABSTRACT

A system includes a utility device, a pressure sensor, and a controller. The pressure sensor is configured to detect a first air pressure at the utility at a first time and a second air pressure at the utility at a second, different time. The controller is configured to receive an operational state indication from the utility device and to receive the first and second air pressure from the pressure sensor. The controller is configured to determine a change in pressure at the utility device using at least the first and second air pressure, determine a first predetermined utility pressure change threshold that is associated with the operational state indication, compare the change in pressure at the utility device to the first predetermined utility pressure change threshold, and, when the change in pressure at the utility device matches that first predetermined threshold, generate an alert relating to the utility device.

### RELATED APPLICATIONS

This application claims priority to U.S. Provisional Application No. 63/348, 195, filed Jun. 2, 2022, the entire content of which is incorporated by reference herein.

### TECHNICAL FIELD

This disclosure relates generally to the use of pressure data to monitor a utility and, in certain embodiments, use of this pressure data to determine one or more actions related to the monitored utility

### BACKGROUND

In terms of utility maintenance, it can be challenging to determine when a utility should be inspected or scheduled for maintenance, and it can be challenging to determine a life expectancy of a utility. In terms of utility tampering, it can be challenging to identify potential tampering of utilities and utility meters such as water, gas, electrical, etc., without using a camera or traditional motion detector.

### SUMMARY

Certain embodiments disclosed herein relate to determining the state of a utility by using pressure data from pressure sensors. In particular such embodiments disclosed herein, noise data included in the pressure sensor data can be used to determine a state of a potentially malfunctioning utility and. for instance, provide a user with an ability to identify a utility that requires maintenance before a warranty for that utility expires. Certain other embodiments disclosed herein relate to identifying potential tampering of a utility using pressure sensor data. In particular such embodiments disclosed herein, pressure data can be used as a safety measure to notify a user of a potential tampering event at a utility.

One embodiment includes a system. This system embodiment includes a utility device, a pressure sensor, and a controller. The pressure sensor is configured to detect a first air pressure at the utility at a first time and a second air pressure at the utility at a second, different time. The controller is configured to receive an operational state indication from the utility device and to receive the first and second air pressure from the pressure sensor. The controller is configured to determine a change in pressure at the utility device using at least the first and second air pressure, determine a first predetermined utility pressure change threshold that is associated with the operational state indication, compare the change in pressure at the utility device to the first predetermined utility pressure change threshold, and, when the change in pressure at the utility device matches that first predetermined threshold, generate an alert relating to the utility device.

Another embodiment includes a utility tamper detection assembly. This utility tamper detection assembly includes a utility housing, a pressure sensor, and a controller. The utility housing at least partially encloses a utility device. The pressure sensor is disposed at the utility housing and configured to detect a first air pressure at the utility housing at a first time and a second air pressure at the utility housing at a second time, where the first time is different than the second time. The controller is in communication with the pressure sensor, and the controller is configured to receive the first air pressure and the second air pressure from the pressure sensor. The controller is configured to determine a change in pressure at the utility housing using at least the first air pressure and the second air pressure, compare the change in pressure at the utility housing to a first predetermined utility housing pressure change threshold, and, when the change in pressure at the utility housing matches the first predetermined utility housing pressure change threshold, generate a tamper alert relating to the utility housing.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

The following drawings are illustrative of particular examples of the present invention and therefore do not limit the scope of the invention. The drawings are not necessarily to scale, though embodiments can include the scale illustrated, and are intended for use in conjunction with the explanations in the following detailed description wherein like reference characters denote like elements. Examples of the present invention will hereinafter be described in conjunction with the appended drawings.

FIG. 1 is a block diagram illustrating an embodiment of a system for using pressure data to monitor a utility, in accordance with one or more techniques described herein.

### DETAILED DESCRIPTION

The following detailed description is exemplary in nature and is not intended to limit the scope, applicability, or configuration of the invention in any way. Rather, the following description provides some practical illustrations for implementing examples of the present invention. Those skilled in the art will recognize that many of the noted examples have a variety of suitable alternatives.

This disclosure describes embodiments that utilize at least pressure data to determine one or more characteristics relating to a utility and, in some instances, use such determined characteristic(s) relating to the utility to determine one or more action.

Certain embodiments of the present disclosure provide a diagnostic tool for utility life expectancy in which the diagnostic tool collects pressure data, including pressure noise data, from one or more pressure sensors (e.g., micro pressure sensors at or adjacent to the utility) and stores the sensor data in a historical database to identify nuances, changes, or adjustments in the pressure sensor data that may relate to the state of a utility and compares the state of the utility to a warranty in order to notify the user of a potential failure so that maintenance may be performed.

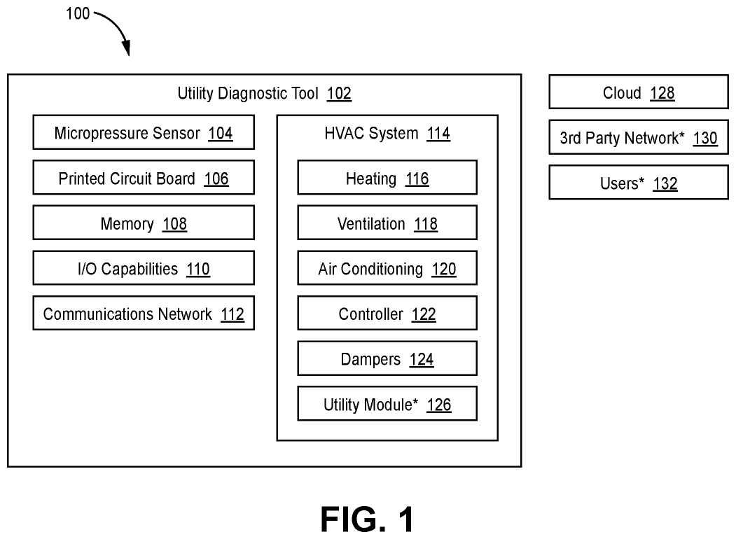

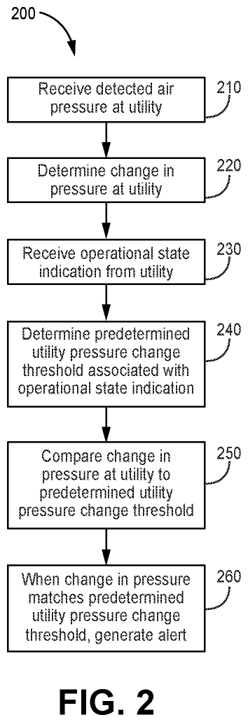

FIG. 1 is a conceptual block diagram of an embodiment of a system 100 for using pressure data to monitor a utility. In the illustrated embodiment, the utility for which pressure data is used to monitor is a heating, ventilation, and air-conditioning (HVAC) system 114. Though in other embodiments various different types of utilities, including appliances and utility cabinets, can be monitoring using similar, or the same, techniques as those disclosed herein.

The system 100 can be configured to provide utility monitoring using pressure data sensed at, or adjacent, the utility. In the embodiment of FIG. 1 where the utility is HVAC system 114, the system 100 can include, in addition to the HVAC system 114, one or more pressure sensors (e.g., micro pressure sensors) 104. a controller (e.g., programmable processing circuitry, such as a printed circuit board) 106, a remote server (“cloud”) 128, and one or more remote user devices 132. The HVAC system 114 can include a heating unit 116, a ventilation unit 118, an air-conditioning unit 120, a HVAC controller 122, one or more air duct dampers 124, and a utility module 126.

The utility module 126 can extract pressure noise data from the pressure data collected by the one or more pressure sensors 104 and store this pressure data, including the pressure noise data, over time. The utility module 126 can utilize historical pressure sensor data to identify variances, or nuances, in the pressure noise data over time. The utility module 126 can use the one or more identified nuances in the pressure noise data over time to determine the state of a utility, such as the HVAC system 114, and compare the state of that utility to a utility warranty retrieved from a third party network 130. Based on this comparison, the utility module 126 can determine if the utility requires maintenance, and, in some instances, generate an output for notifying a user, such as at a specified remote user device 132.

Thus. in operation. the system 100 may utilize the utility module 126 to collect pressure sensor data, such as pressure noise data relating to the monitored utility, from one or more pressure sensors located throughout the HVAC system 114 and/or near other premises utilities, such as boilers, refrigerant lines, water pumps, etc. The utility module 126 can store the sensor data in a historical database, such as memory 108, to identify nuances within the pressure sensor data. For example, if a refrigerant line starts to become frozen, it will generate larger pressure turbulence than if it were clear. The utility module 126 may examine the nuances to determine the state of the utility and compare the utility to a warranty received from the third party network 130 (e.g., received over the third party network 130 from a third party utility manufacturer). Then. the utility module 126 determine if the utility (e.g., HVAC system 114) requires maintenance before the expiration of the warranty, and notify the user, such as at a specified remote user device 132. For example, if the sensor data near a boiler has pressure noise data that is becoming greater over time, then there may be a buildup of debris on the boiler's heat exchanger, and the utility module 126 can use the warranty data from the third party network 130 to notify the user that the boiler should be scheduled for maintenance while it is still under warranty.

In another embodiment, for instance where the monitored utility is a utility cabinet, the system 100 can be configured to provide provides a utility safety system in which the utility module 126 is configured to serve as a detection module that polls (e.g., continuously) and receives pressure sensor data, such as pressure fluctuation data. pressure noise data, or pressure turbulence data, from the one or more pressure sensors 104, for instance located at or near the utility cabinet. The collected pressure fluctuation data, pressure noise data, or pressure turbulence data can be used to determine if the pressure sensor data exceeded a predetermined threshold that identifies a potential tampering situation of a utility or utility meter at the cabinet and notifies the user of the potential tampering.

Thus, in operation, the utility safety system, such as system 100, can utilize the utility module 126 to poll (e.g., continuously) the one or more pressure sensors 104 and receiving pressure sensor data from these one or more pressure sensors 104, such as pressure fluctuation data, pressure noise data, or pressure turbulence data, located at (e.g., within) or near the utility cabinet. The collected pressure sensor data can be compared to a pressure threshold database, which contains predetermined pressure thresholds and one or more indicators, associated with such predetermined thresholds. as to what the exceeding data may mean, and if the collected sensor data exceeds the thresholds, a user can be notified (e.g., at remote user device 132) of the indicator. For example, if there is a micro pressure sensor near an electrical meter or within a boiler cabinet, and the collected pressure fluctuation data, pressure noise data, or pressure turbulence data exceeds the threshold stored in the threshold database, the user can be notified, such as unscheduled electrical meter check potential tampering or inadequate seal on the boiler cabinet.

Various examples of the disclosure have been described. Any combination of the described systems, operations, or functions is contemplated. These and other examples are within the scope of the following claims.

What is claimed is:

1. A system comprising:
a utility device:
a pressure sensor configured to detect a first air pressure at the utility at a first time and a second air pressure at the utility at a second time, the first time being different than the second time; and
a controller in communication with the utility device and the pressure sensor, wherein the controller is configured to receive an operational state indication from the utility device, and wherein the controller is configured to receive the first air pressure and the second air pressure from the pressure sensor, and
wherein the controller is configured to determine a change in pressure at the utility device using at least the first air pressure and the second air pressure, determine a first predetermined utility pressure change threshold that is associated with the operational state indication, compare the change in pressure at the utility device to the first predetermined utility pressure change threshold, and, when the change in pressure at the utility device matches the first predetermined utility pressure change threshold. generate an alert relating to the utility device.

2. The system of claim 1, wherein, when the change in pressure at the utility device matches the first predetermined utility pressure change threshold, the controller is further configured to determine if a warranty for the utility device applies.

3. The system of claim 2, wherein the controller is configured to determine if the warranty applies by comparing a time at which the change in pressure at the utility device matches the first predetermined utility pressure change threshold and a term of the warranty.

4. The system of claim 3, wherein the controller is configured to determine if the warranty applies by comparing the operational state indication and one or more operational conditions specified by the warranty.

5. The system of claim 2, wherein the controller is configured to store a plurality of warranty data packets relating to different utility devices, and wherein the controller is configured to select a first warranty data packet, from the plurality of warranty data packets, as relating to the utility device using a utility device identifier received from the utility device.

6. The system of claim 5, wherein the controller is configured to transmit a maintenance scheduling request to a third party when the controller determines that the warranty for the utility device applies.

7. The system of claim 1, wherein the alert relating to the utility device includes a notice that the utility device needs maintenance.

8. The system of claim 7, wherein the controller is configured to transmit the alert to a remote user device.

9. The system of claim 1, wherein the utility device is selected from the group consisting of: a heating, ventilation, and air conditioning (HVAC) unit and a water heater.

10. The system of claim 9, wherein the operational state indication from the utility device includes data relating to an operation being executed by the utility device when the first air pressure and the second air pressure are received from the pressure sensor.

11. A utility tamper detection assembly comprising:
a utility housing at least partially enclosing a utility device:
a pressure sensor at the utility housing and configured to detect a first air pressure at the utility housing at a first time and a second air pressure at the utility housing at a second time, the first time being different than the second time; and
a controller in communication with the pressure sensor, wherein the controller is configured to receive the first air pressure and the second air pressure from the pressure sensor,
wherein the controller is configured to determine a change in pressure at the utility housing using at least the first air pressure and the second air pressure, compare the change in pressure at the utility housing to a first predetermined utility housing pressure change threshold, and, when the change in pressure at the utility housing matches the first predetermined utility housing pressure change threshold, generate a tamper alert relating to the utility housing.

12. The assembly of claim 11, wherein the controller is in communication with the utility device, wherein the controller is further configured to receive an operational state indication from the utility device and determine the first predetermined utility housing pressure change threshold using the operational state indication.

13. The assembly of claim 11, further comprising:
an access door at the utility housing. wherein the first time is when the access door is closed and the second time is when the access door is open.

14. The assembly of claim 13, wherein the tamper alert relates to the access door being open.

15. The assembly of claim 13, wherein when the access door is closed the utility device is concealed within the utility housing and when the access door is open the utility device is accessible within the utility housing.

16. The assembly of claim 11, wherein the controller is configured to generate the tamper alert when a time at which the change in pressure at the utility housing matches the first predetermined utility housing pressure change threshold differs from a prescheduled utility device maintenance time.

17. The assembly of claim 16, wherein the controller is configured to receive and store a utility maintenance schedule that includes the prescheduled utility device maintenance time.

18. The assembly of claim 11, wherein the controller is configured to transmit the tamper alert to a remote user device.

19. The assembly of claim 11, wherein the utility device is selected from the group consisting of: an electrical meter and a boiler.

20. The assembly of claim 19, wherein the controller is in communication with the utility device, wherein the controller is further configured to receive an operational state indication from the utility device, and wherein the operational state indication from the utility device includes data relating to an operation being executed by the utility device when the first air pressure and the second air pressure are received from the pressure sensor.
